(19) United States
(12) Patent Application Publication
(10) Pub. No.: US 2017/0175990 A1
(43) Pub. Date: Jun. 22, 2017

(54) LED ARRAY APPARATUS

(71) Applicant: Jitendra Patel, ROLLING HILLS ESTATE, CA (US)

(72) Inventor: Jitendra Patel, ROLLING HILLS ESTATE, CA (US)

(21) Appl. No.: 15/138,693

(22) Filed: Apr. 26, 2016

Related U.S. Application Data
(60) Provisional application No. 62/268,369, filed on Dec. 16, 2015.

(51) Int. Cl. F21V 29/70; H05K 1/02; H05K 1/18

(52) U.S. Cl. CPC F21V 29/70; H05K 1/181; H05K 1/0204; F21Y 2101/02; H05K 2201/10106; H05K 2201/066

(57) ABSTRACT

An LED apparatus is provided in which at least one LED is simply and reliably mounted. LEDs are connected mechanically, electrically, and thermally within a lighting assembly. An LED comprises an emission layer on a substrate such as a circuit board. The circuit board is both an LED support and a conductor for connection to LED terminals. A frame has a cutout receiving the printed circuit board. The frame is fastenable to a heat dissipating surface. The cutout also defines cantilevered beams cut out within the surface of the frame. The cantilevered beams surround the LED to distribute force across the LED. The circuit board includes copper vias providing power to terminals on the LED. The terminals may be soldered to the power contact without the need for additional wiring.

### CROSS-REFERENCE TO RELATED APPLICATIONS

This application claims priority from Provisional Patent Application Ser. No. 62/268,369 filed on Dec. 16, 2015, which is incorporated by reference herein in its entirety.

### BACKGROUND OF THE INVENTION

Field of the Invention

The present subject matter relates to a light emitting diode (LED) apparatus in which an emission layer is placed on a substrate including at least one circuit cooperating with the LED emission layer, the LED apparatus interacting in a structure providing heat dissipation and light projection.

Background

Light emitting diodes have come into wide use due to their energy efficiency in converting electricity into light. One application comprises one or more light emitting diodes supported to a substrate. The substrate may be planar or approximately planar. An individual light emitting diode generally comprises a matrix, or array, of smaller light emitting components. This is generally referred to in the art as an array. For convenience in description, the light emitting unit comprising an array of smaller light emitting components is referred to herein as a light emitting diode (LED).

The term array in the present specification is used to describe an arrangement of light emitting diodes. A number of light emitting diodes may be arranged in an array. Significant applications of LED arrays include high-bay lighting, street lighting, and canopy lighting.

Many parameters must be controlled to provide for efficiency and reliability. A major concern is removal of heat produced by the LED. Heat causes significant degradation in the number of lumens produced by an LED if the heat transfer from LEDs to a heat sink or other body has not been maximized. It is necessary to be able to predict that after a given number of years, the LED will provide at least a predetermined percentage of the illumination level provided at installation. This enables a warranty to be provided for the given number of years.

Another concern is reliable mechanical mounting of a single LED or multiple LEDs in an array. Reliable mechanical mounting requires substantial uniformity in the stress applied to LEDs or applied to circuit boards on which the LEDs are mounted. Non-uniform mounting pressure affects thermal conduction from an LED to another layer of an assembly. In order to retain LEDs in place at a distance from a fastener, it may be necessary to have increased pressure on LEDs close to the fastener. This can result in structural failure of the LED or a substrate over time. Connection of power to LEDs can also present a challenge.

For purposes of the present description, an LED comprises a light emitting layer formed on a surface of a substrate Mounting means which maintain the substrate against a heat dissipating surface provide non-uniform pressure on the circuit board. The uneven pressure may crack the substrate. However, the crack may not occur until three months after installation and will not be readily detectable.

Prior art apparatus have particular shortcomings which, as a group, have not been addressed in the art. Prior arrangements also include wiring requirements for connecting the LED to a power source which require additional steps beyond plugging an LED into a holder. Many different structures are provided for connecting power to an LED from another layer of an assembly. These structures tend to be complex.

U.S. Pat. No. 9,109,787 discloses an LED and heat sink module for mounting in a lighting assembly. A mounting assembly captures LED modules between top and bottom mounting plates. Each LED is mounted to a heat conducting body in the LED assembly. The LED modules are sandwiched between two plates by screws. As the number of LEDs in the assembly increases, distance between screws increases and non-uniformity of pressure on the LED modules increases. Inordinate stress may be placed on modules closer to the screws, thus decreasing reliability. Complexity in construction is provided by the need to run discrete power leads from a power socket to a substrate supporting the LEDs.

United States Patent Application Publication No. 20110063849 discloses an LED light module removably coupleable to a receiving lighting assembly. The module comprises a plurality of layers within a cylindrical housing. An LED lighting element is coupled to a thermal interface member and is configured to resiliently contact one or more thermally conductive surfaces of a receiving lighting assembly. The LED lighting element is included on a thermal interface member and must be connected to a circuit board in a different layer. The LED light module also comprises one or more resilient members configured to generate a compression force when the LED light module is installed in the receiving lighting assembly. The compression members comprise metal loops disposed in the nature of leaf springs. However, the metal loops may simply be replaced by a gasket. The LED light module further comprises one or more electrical contact members of the LED light module configured to releasably contact one or more electrical contact elements of a socket of the receiving lighting assembly. The contact comprises a leaf spring. A leaf spring is subject to formation of corrosion and creating an impedance at the contact.

United States Patent Application Publication No. 20150167910 discloses a method for producing a light emitting diode arrangement. A plurality of LED modules comprises at least one radiation emitting semiconductor component on a carrier body. A separately fabricated connection carrier provides a mechanically stable and electrically conductive connection between the carrier bodies of two LED modules. LED modules must be provided in pairs. A single assembly is not provided in which a selectable number of LEDs may be included.

U.S. Pat. No. 7,866,850 discloses a light fixture assembly comprising an LED sz5frfedi919whousing. Operation of the compression element from a first position to a second position generates a compression force which reduces thermal impedance between the LED assembly and a thermally-conductive housing. The LED must be connected to a power terminal block through intermediate layers, increasing difficulty in assembly and reliability of ohmic contact.

United States Patent Application Publication No. 20130183779 discloses an LED module mounted on parallel conducting wires in order to connect to the LED. The LED assembly is potted. This assembly may not easily be reassembled.

### SUMMARY

Briefly stated, in accordance with the present subject matter, an LED apparatus is provided in which at least one LED is simply and reliably mounted. LEDs are connected mechanically, electrically, and thermally within a lighting assembly. For purposes of the present description, an LED comprises a light emitting layer formed on a surface of a substrate. An LED emission layer is provided on a substrate. The circuit board is both an LED support and a conductor for connection to LED terminals. In one form, a frame is provided with a cutout receiving the substrate. The frame is fastenable to a heat sink or other heat dissipating surface. The cutout also defines cantilevered beams cut out within the surface of the frame. The cantilevered beams surround the LED on opposite sides allowing substantially uniform force to be applied to the circuit board across the extent of the LED. The use of the cantilevered beams provides the added benefit of uniform pressure on each LED in an array. In an alternating current embodiment, the circuit board includes copper vias providing rectified power to terminals on the LED. The terminals may be soldered to the power contact without the need for additional wiring. The frame and the circuit board are substantially coplanar at a lower side. When the frame and the circuit board are fastened to a surface, heat transfer is maximized.

The present subject matter provides desirable qualities in an LED lighting fixture, namely selectability of the number of LEDs, reliability of the LEDs over time to provide a preselected level of illumination, non-hazardous arrangements for connecting power leads to the LED, and reliable methods of maintaining a circuit board in a holder on which an LED is mounted.

It is also highly desirable to provide an LED apparatus which is simple in construction and easy to manufacture from basic materials. In many applications, an LED lamp must be certified as safe, primarily by such standard bodies as Underwriters Laboratories (UL), the CE mark of the European Community, and the Canadian Standards Association (CSA). The present subject matter provides for simple and safe construction.

### BRIEF DESCRIPTION OF THE DRAWINGS

FIG. 1A is a perspective view including a light-projecting surface of a lighting apparatus for housing and interacting with an LED assembly according to the present subject matter;

FIG. 1B is a perspective view illustrating an opposite side of the apparatus of FIG. 1A;

FIG. 2A is a perspective view of the lighting apparatus of FIG. 1A with the diffuser removed;

FIG. 2B is a perspective view of the chamber member included in FIG. 2A;

FIG. 2C is a perspective view of an alternate embodiment in which an alternative form of LED apparatus is incorporated;

FIG. 3 is a cross-sectional view of the lighting apparatus taken along line 3-3 in FIG. 2A;

FIG. 4A is an isometric view of an LED used in one exemplary embodiment;

FIG. 4B is an isometric view of an LED used in another exemplary embodiment;

FIG. 5A is a perspective view of an embodiment comprising a single LED;

FIG. 5B is a cross-sectional view taken along line 5-5 of FIG. 5A;

FIG. 5C is a plan view of FIG. 5A with an insulation layer removed;

FIG. 5D is a plan view of an alternate frame for mounting a plurality of LEDs;

FIG. 6 is a plan view of the LED assembly illustrating additional features for hazardous environments;

FIG. 7 is a perspective view of an LED assembly including additional circuity on a printed circuit board;

FIG. 8A is an isometric view of the circuit board seen in FIG. 4B;

FIG. 8B is an isometric view of the underside of the assembly of FIG. 8A;

FIG. 9 is a perspective view of a frame for holding a plurality of LEDs;

FIG. 10 is an exploded perspective view of the frame, the plurality of LEDs, and a mounting surface comprising a heat sink; and

FIG. 11 is a plan view of the arrangement of FIG. 10.

### DETAILED DESCRIPTION

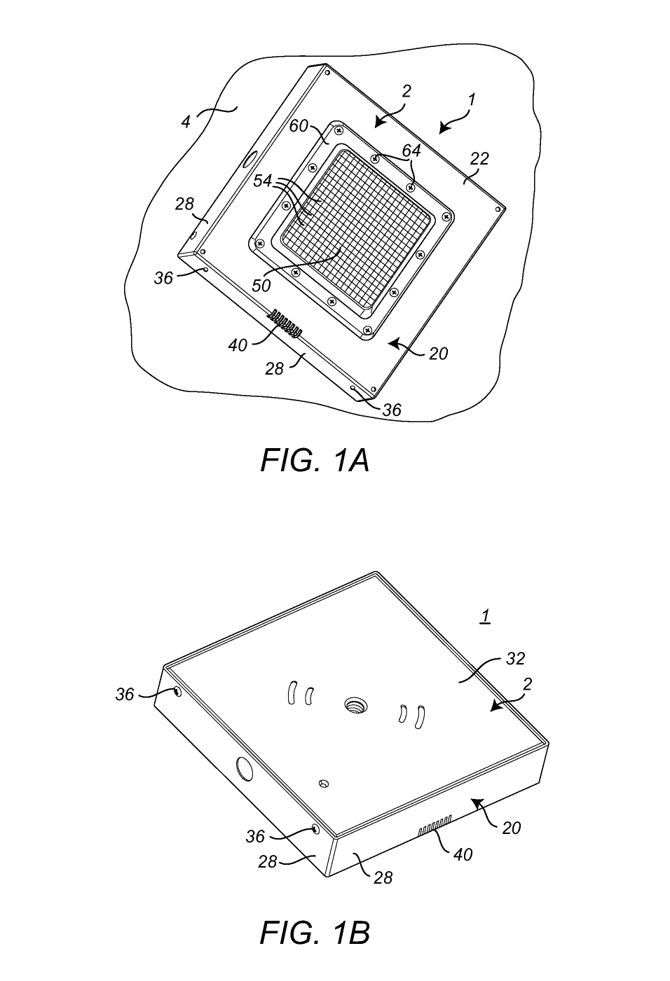

FIG. 1A is a perspective view including a light-projecting surface of a lighting apparatus 1 for housing and interacting with an LED assembly according to the present subject matter. FIG. 1B is a perspective view illustrating an opposite side of the apparatus of FIG. 1A. FIG. 1A and FIG. 1B are discussed together.

The lighting apparatus 1 may take many different forms. Typical applications include high bay lighting, street lighting, and ceiling lighting. In the present illustration, the lighting apparatus 1 comprises a canopy light 2. A canopy is a permanent structure comprising a roof and supporting building elements. The area underneath the canopy is at least partially open to either the elements or to the volume of an enclosed space containing the canopy. A canopy may be described as a ledge projecting horizontally from a sidewall. In a typical application, the canopy light 2 is installed onto a horizontally disposed overhang 4. In the present description, terms such as horizontal and vertical are used to describe relative orientation of components. They do not necessarily imply any orientation of the lighting apparatus 1 with respect to the surface of the earth.

The canopy light 2 comprises a housing 20 generally provided in the form of a box. The housing 20 comprises a lower surface 22. “Lower” is used to denote that the lower surface 22 is substantially parallel to the overhang 4 rather than to denote any particular spatial disposition. The housing 20 comprises sidewalls 28. The housing 20 further comprises a mounting plate 32 (FIG. 1B). To install the canopy light 2, mounting plate 32 is fastened to the overhang 4. The sidewalls 28 are each secured at an upward vertical end thereof to the mounting plate 32. Fasteners 36 each extend through a sidewall 28 and are screwed into the mounting plate 32. The housing 20 may include vents 40. The vents 40 may comprise apertures at mating edges of the lower surface 22 and a side wall 28.

Light is projected through a diffuser 50. The diffuser 50 may include a matrix of individual lenses 54. Various materials may be used to make the diffuser 50. One suitable example for industrial applications is polycarbonate resin. Residential applications may use glass. The diffuser 50 is held to the lower surface 22 by a peripheral bracket 60. Diffuser fasteners 64 extend through the peripheral bracket 60 and are received in the lower surface 22.

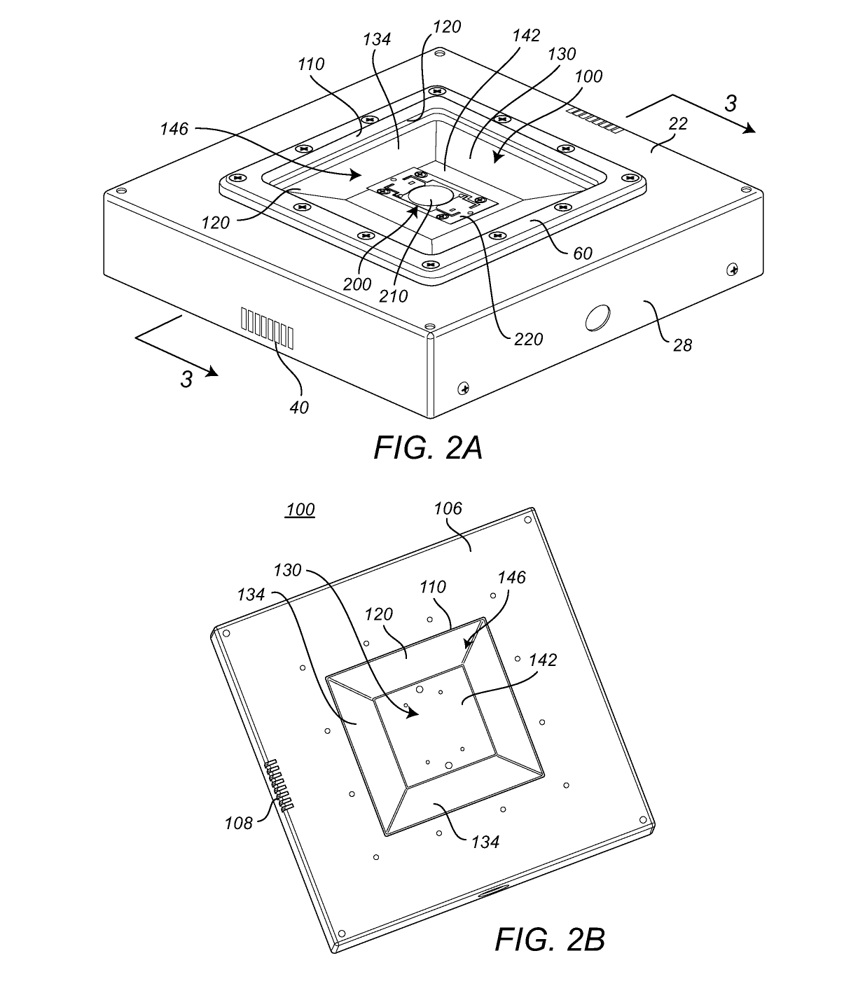

FIG. 2A is a perspective view of the lighting apparatus of FIG. 1A with the diffuser 50 removed. FIG. 2B is a perspective view of a chamber member included in the structure of FIG. 2A. FIGS. 2A and 2B are discussed together. FIG. 2C is a perspective view of an alternate embodiment in which an alternative form of LED apparatus is incorporated.

A chamber member 100 is affixed to an interior wall of the lower surface 22. The chamber member 100 comprises a mounting surface 106 which is fastened to the interior wall of the lower surface 22. The mounting surface 106 includes a chamber perimeter 110 surrounding an opening 120 through which light is projected. The opening 120 is substantially in registration with the diffuser 50 (FIG. 1A). A chamber 130 is provided for housing light-emitting elements further discussed below. In the present illustration, the chamber 130 comprises a truncated pyramid 146 extending upwardly from the mounting surface 106. The chamber 130 includes tilted sidewalls 134 closed by a horizontally disposed lighting support surface 142. The lighting support surface 142 is thermally conductive. Heat may be radiated from the lighting support surface 142. Heat may escape through the vents 40. The mounting surface 106 includes vents 108 in registration with the vents 40.

In FIG. 2A an LED apparatus 200 is illustrated mounted to the lighting support surface 142. The LED apparatus includes an LED 210 mounted in a frame 220.

In the illustration of FIG. 2C an alternative frame 234 is provided including first and second frame portion 236 and 238 laterally displaced from each other. LEDs 240 and 242 are mounted in the frame portions 236 and 238 respectively.

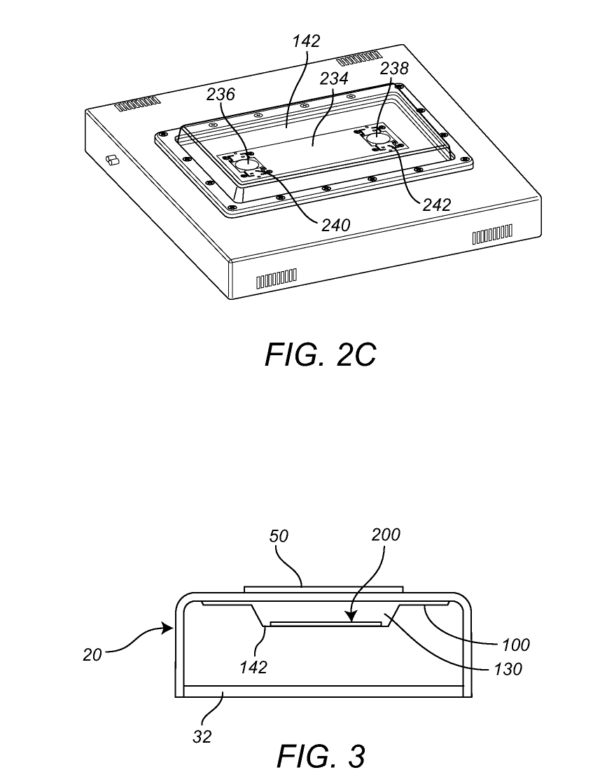

FIG. 3 is a cross-sectional view of the lighting apparatus taken along line 3-3 in FIG. 2A. The chamber 130 is enclosed within the volume of the housing 20. The lighting support surface 142 is displaced from an interior surface of the mounting plate 32 (FIG. 1B). Room is allowed for convection currents. Heat is thermally conducted from the LED apparatus 200 to the lighting support surface 142. This heat is dissipated via convection from the lighting support surface 142.

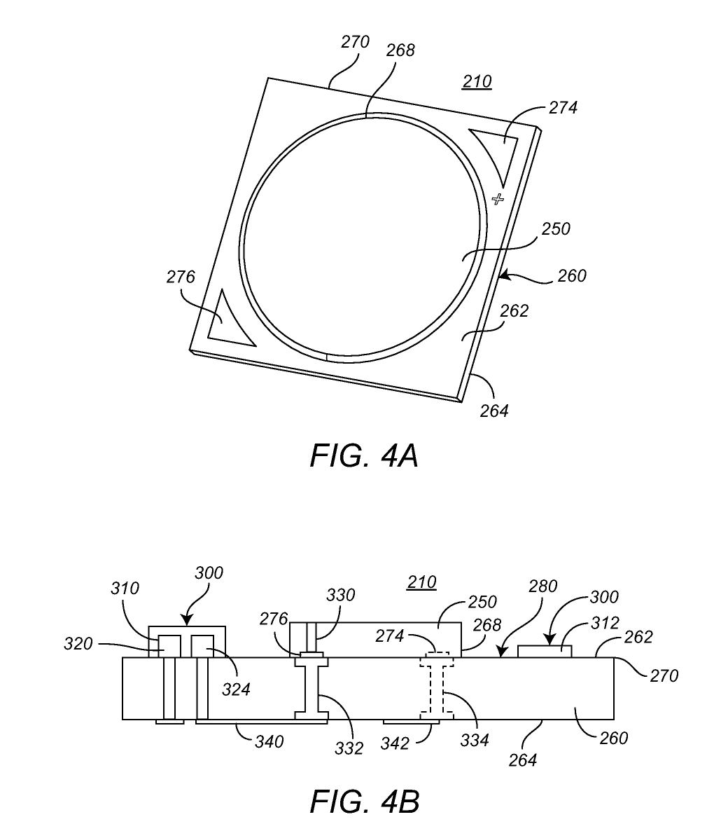

FIG. 4A and FIG. 4B are each a view of one form of LED 210. The term “LED” is used in many different ways in the art. In the present description, the LED 210 comprises a light-emitting layer 250 mounted on a substrate 260. The light-emitting layer 250 comprises a matrix of light-emitting components. The substrate 260 may comprise a printed circuit board. For convenience, a substrate including the printed circuit board may be referred to as a substrate when referring to the shape of the substrate and as a printed circuit board when referring to circuitry in or on the substrate 260. The substrate 260 comprises an upper surface 262 and a lower surface 264. A perimeter 268 of the light-emitting layer 250 is contained within a perimeter 270 of the substrate 260. The embodiment of FIG. 4A is intended to have a DC power input. A positive terminal 274 and a negative terminal 276 are formed adjacent opposite corners of the substrate 260.

FIG. 4B illustrates an alternating current embodiment of the LED 210 in the form of an LED 280. The same reference numerals are used to denote components corresponding to components in FIG. 4A. Circuit components 300 are mounted on the upper surface 262 of the substrate 260. The circuit components 300 may be mounted on either side or both sides of the light-emitting layer 250. The substrate 260 is formed with an upper surface 262 having dimensions selected to support a preselected group of circuit components 300. AC input terminals 320 and 324 are mounted on the upper surface 262. A rectifier circuit 310 is coupled to receive an input from the AC terminals 320 and 324 and to provide a DC output. The remaining circuitry 312 within the group of circuit components 300 is selected to perform other preselected functions.

Copper vias 332 and 334 are formed in the substrate 260 located adjacent to and conducting power to the terminals 276 and 274 respectively. Circuit traces 340 and 342 conduct power from the rectifier 310 to the vias 332 and 334 respectively. In this manner, connections may be made without the need for additional wires.

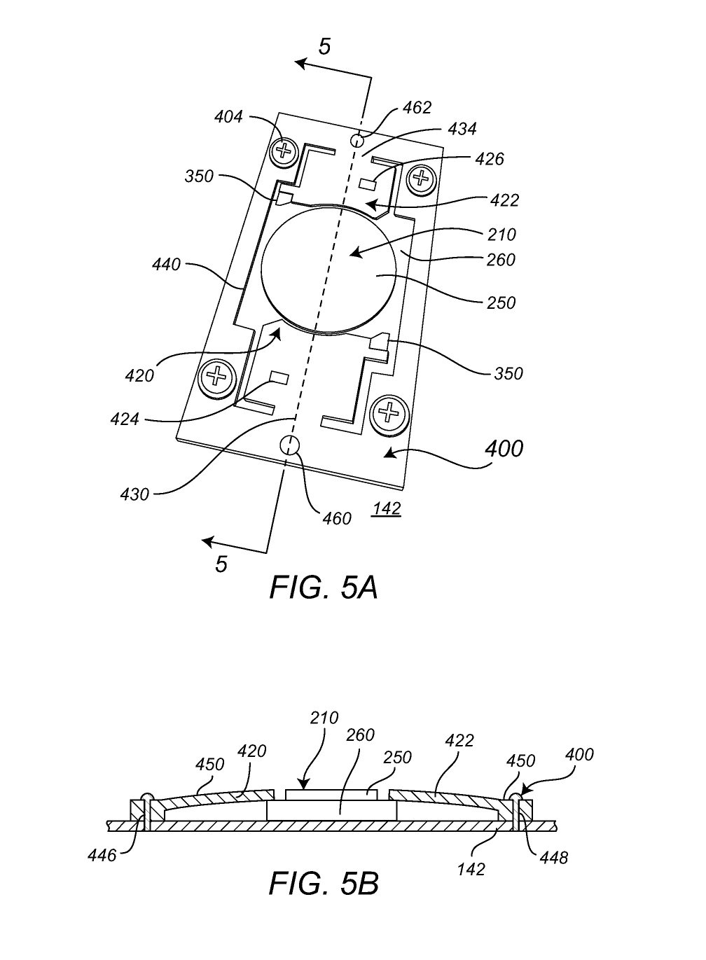

FIG. 5A is a perspective view of an embodiment comprising a single LED 210. FIG. 5B is a cross-sectional view taken along line 5-5 of FIG. 5A. FIG. 5C is a plan view of FIG. 5A. FIG. 5A illustrates a frame 400 maintaining the LED 210 in engagement with the lighting support surface 142 of the chamber member 100 (FIG. 2A). The frame 400 is fastened to the lighting support surface 142 by fasteners 404. The fasteners 404 may comprise machine screws. Other forms of fasteners may be used. The frame 400 has a cutout 440. As seen in FIG. 5C, a plan view of FIG. 5A, the cutout 440 is shaped to receive the substrate 260. The cutout 440 is also shaped to define first and second frame portions 420 and 422 unitary with the frame 400. The first and second frame portions 420 and 422 are positioned to be in the vertical path of the substrate 260. As best seen in FIG. 5B, vertical projections of the first and second frame portions 420 and 422 are in registration with portions of the substrate 260.

In order to provide support, the first and second frame portions 420 and 422 need to be resiliently mounted. A first frame portion 420 is at an inward end of a cantilevered arm 424. “Inward” is used to denote a direction toward a center of the cutout 440. The second portion 422 is at an inward end of a second cantilevered arm 426. The use of the cantilevered arms 424 and 426 provides the added benefit of uniform pressure on each LED 210 in an array. Reliability of the LEDs to provide a preselected level of illumination over time is facilitated by mechanical and thermal engagement of the frame 400 with the surface 142. As seen in FIG. 5B the LED package 200 (FIG. 3) has a lower surface mounted for substantially uniform force against the surface 142. Uniform force on the substrate 260 minimizes stress and mechanical failures such as cracking of the substrate 260.

Cantilevered arms 424 and 426 (FIG. 5A) are cut out within the surface of the frame 400. The cantilevered arms 424 and 426 surround the LED 210 on opposite sides allowing substantially uniform force to be applied to the circuit board across the extent of the LED 210.

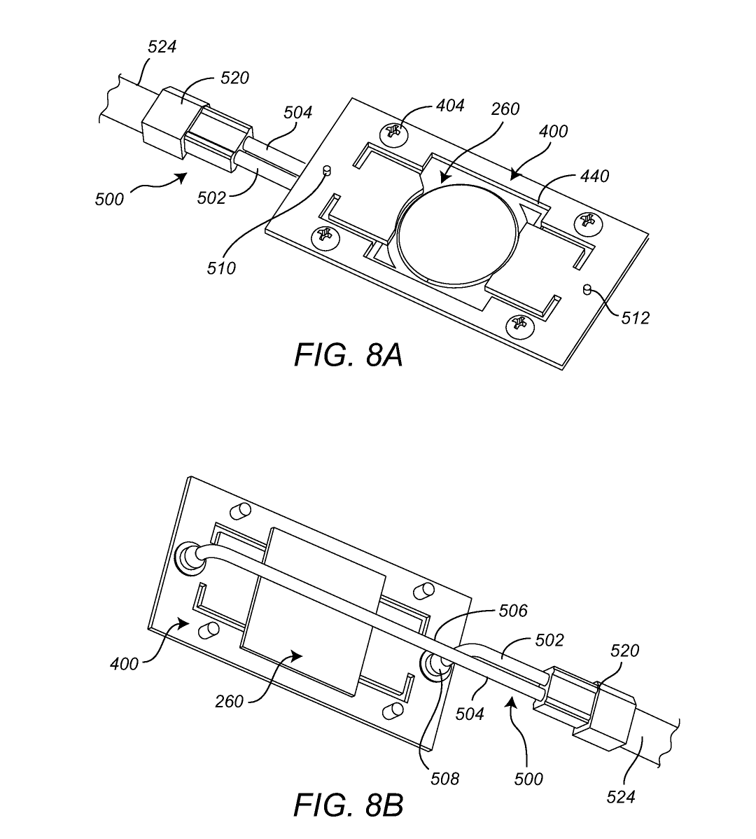

Electrodes 446 and 448 extend through opposite ends of the frame 400 for connection to the substrate 260 along circuit traces illustrated in FIG. 5C. The frame 400 is coated with an insulation layer 450 (FIG. 5B). In FIG. 5C the frame 400 is shown with the insulation layer 450 removed. Connection of power to the electrodes 446 and 448 is further explained with respect to FIG. 8A and FIG. 8B.

In FIG. 5B, the cantilevered arms 424 and 426 press the substrate 260 against the lighting support surface 142. A number of factors influence the force applied by the cantilevered arms 424 and 426. In one preferred form, the frame 400 comprises glass-epoxy printed circuit board material. Factors in determining the amount of force applied to the substrate 260 include the length and shape of the first and second cantilevered arms 424 and 426, the thickness of the frame 400, the material used to make the frame 400, and the shape of the first and second connecting portions 430 and 434 (FIG. 5A). The angular displacement of the first and second cantilevered arms 424 and 426 is a function of the relative thicknesses of the frame 400 and the substrate 260.

FIG. 5C is a plan view of the frame 400 with the insulating layer 450 removed. A trace 460 is connected to the electrode 446 and continues to a position in registration with the LED terminal 274. A trace 462 is connected to the electrode 448 and continues to a position in registration with the LED terminal 276. A solder joint 464 is formed to connect the terminal 274 to the trace 460. A solder joint 466 is formed to connect the terminal 276 to the trace 462. This structure allows the LED 210 (FIG. 2A) to be connected to a DC power supply without the need for a separate wire to connect each LED terminal 274 and 276 to a power source. Manufacture is simplified and cost is reduced. Reliability is enhanced.

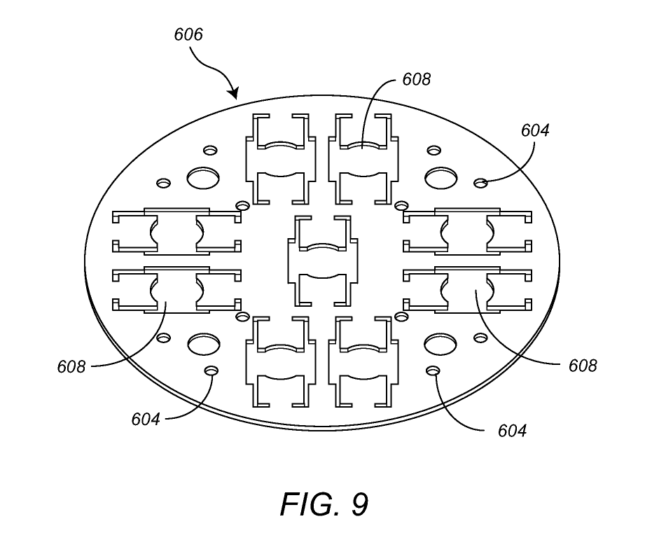

FIG. 5D is a plan view of an alternative frame 458 for mounting a plurality of LEDs 210. The frame 458 is an alternative to the frame 400. The frame 458 is suitable for use, for example, in the lighting assembly of FIG. 2C. A plurality of cutouts 440, e.g., three in the present illustration, are provided. The frame 458 is rectangular, and cutouts 440 are parallel to each other. In other forms, the frame 458 may have other shapes and support differing numbers of LEDs 210. An example is seen in FIG. 9, which is further discussed below.

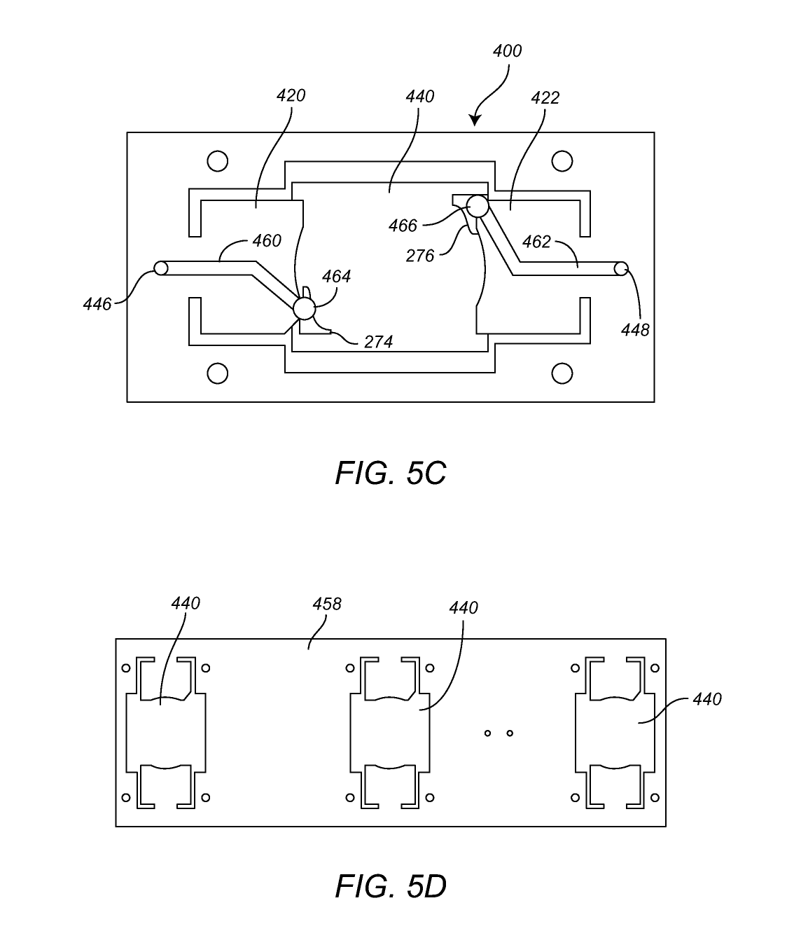

FIG. 6 is a view of the LED assembly 200 illustrating additional features useful in hazardous environments. The same reference numerals are used to denote components corresponding to those in FIG. 4, FIG. 5A, FIG. 5B. and FIG. 5C. At least one shroud member 480 is provided in order to prevent sparks or other heating effects that may occur around exposed conductors. Exposed conductors in the LED assembly 200 include the solder joints at the positive terminal 274 and the negative terminal 276. In the present illustration, a shroud member 480 is placed on the lighting support surface 142 and comprises a set of walls 482 surrounding the LED assembly 210. The shroud member 480 is placed to prevent sparks or other heating effects from reaching the diffuser 60 (FIG. 1). Consequently, the present construction will enable the user to comply with safety standards in a much more efficient manner than available with prior art apparatus. The shroud member 480 is shaped to minimally affect light issuing from the light-emitting surface 250.

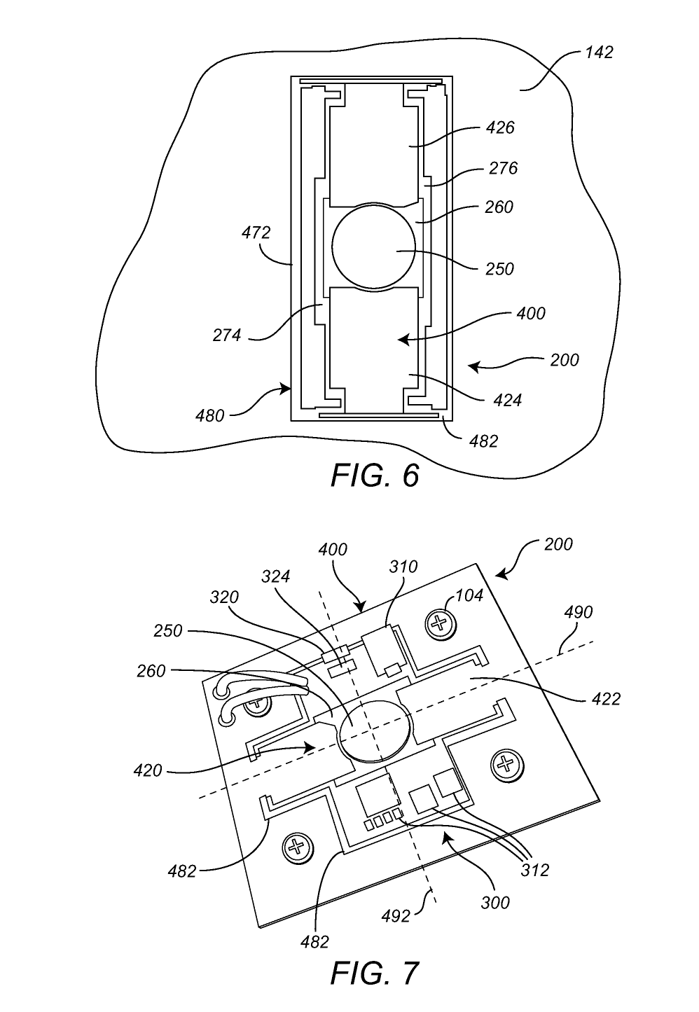

FIG. 7 is a perspective view of an LED assembly 200 including additional circuity on the printed circuit board. The same reference numerals are used to denote components corresponding to those in FIG. 4, FIG. 5A, FIG. 5B, and FIG. 5C. The embodiment of FIG. 7 is suitable for use with an AC power input. The frame 400 comprises an alternative cutout 482 which accommodates the substrate 260. The cantilevered arms 424 and 426 define a line 490 intersecting the LED 210. The cutout 482 and the substrate 260 are disposed along a line 492 which is perpendicular to the line 490. Separate substrate sections are disposed on opposite sides of the LED 210. The separate substrate sections each support the circuitry 300.

FIG. 8A is an isometric view of a DC version of the circuit board seen in FIG. 4B. FIG. 8B is an isometric view of the underside of the assembly of FIG. 8A. The substrate 260 is illustrated in registration with the cutout 440 in a juxtaposition in which the LED apparatus 210 is not pressed against the lighting support surface 142 (FIG. 2C). A power cable 500 includes a first conductor 502 and a second conductor 504 which are connected to the substrate 260 via terminals 274 and 276 (FIG. 5C) respectively. The power cable 500 is connected to a power source 524 by a plug 520. The trace 460 of FIG. 5C connects the terminal 274 to the conductor 502. The trace 462 of FIG. 5C connects the terminal 476 to the conductor 504.

The embodiment of FIGS. 9-11 includes an array of LEDs 210. A frame provides substantially equal pressure on a plurality of the LEDs 210 in a lamp assembly. Cutouts 608 are arranged substantially symmetrically in a frame 606. When fasteners are placed to maintain the frame 606 in engagement with the surface 622, force is evenly distributed against the LEDs 610. Mechanical integrity and minimal stress are provided. Simplified wiring may also be provided.

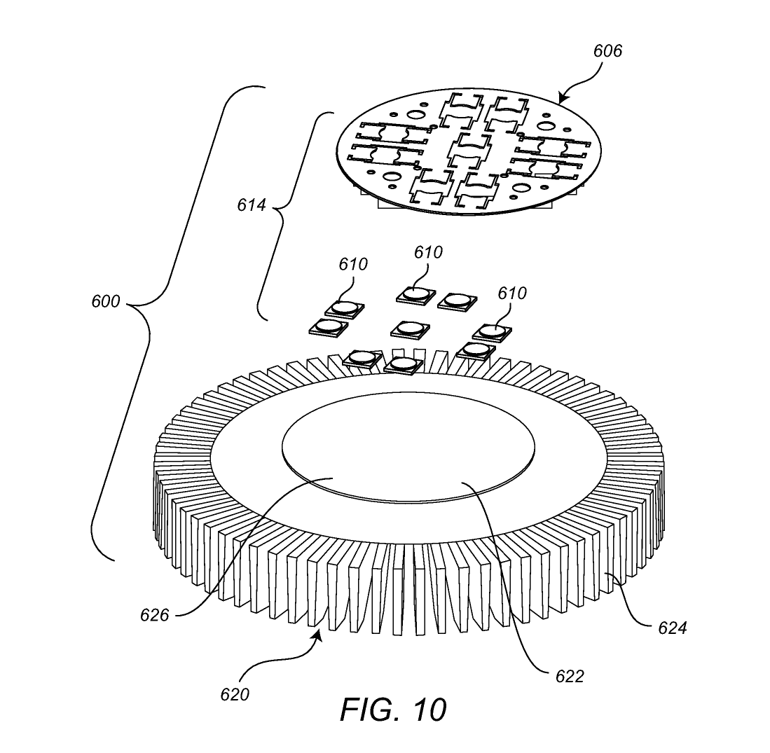

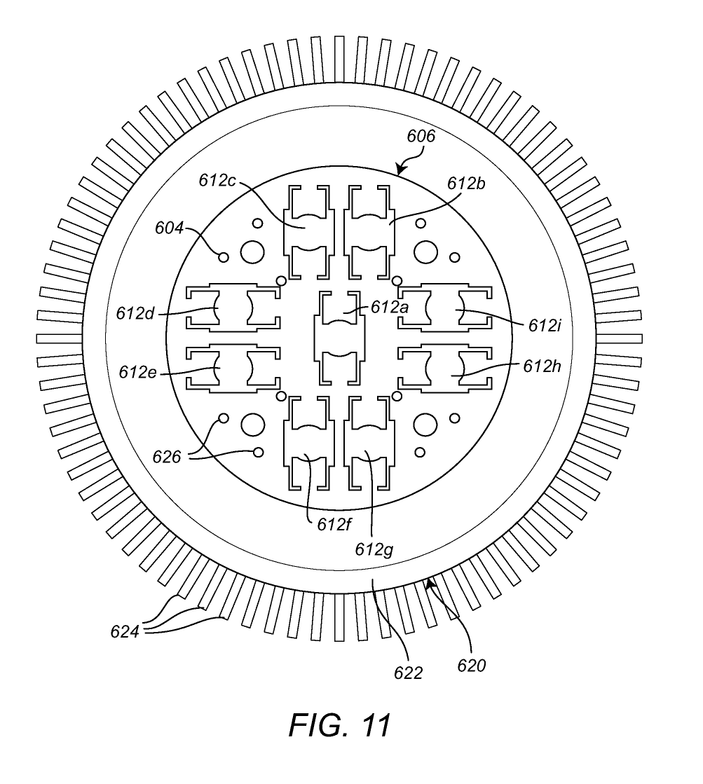

FIGS. 9, 10, and 11 together illustrate a lighting assembly 600 for enclosure in a housing such as the housing 24 in FIG. 1A. FIGS. 9, 10, and 11 are discussed together. FIG. 9 is a perspective view of a frame 606 with apertures 604 and cutouts 608. The apertures 604 receive fasteners. The cutouts 608 provide for structures that retain each LED 610 in a proper position for cooperatively providing lighting. Any or all of the cutouts 608 hold an LED 610 in the LED frame 606. The frame 606 and the LEDs 610 taken together comprise an LED assembly 614. In the present description, each combination of an LED 610 and the adjacent portion of the frame 600 is referred to as a subassembly 612 (FIG. 11). The embodiment of FIGS. 9-11 comprises components corresponding to a plurality of the LED assemblies 200 in the embodiments of FIGS. 1-8. FIG. 10 is an exploded perspective view of the frame 606, the plurality of LEDs 610, and a mounting surface 622, which is an upper surface of a heat sink 620. FIG. 11 is a plan view of the arrangement of FIG. 10.

In the present embodiment, nine subassemblies 612 are provided. The subassemblies are referred to as 612a through 612i. In the present embodiment, the LED unit 612a is positioned at a center of the frame 606. First, second, third, and fourth pairs of subassemblies 612 are provided. Pairs of subassemblies, 612b-612c, 612d-612e, 612f-612g, and 612h-612i are spaced equidistantly from a center of the frame 606 and are equiangularly displaced.

In the present embodiment, the LED assembly 614 is mounted to the heatsink 620 comprising the mounting surface 622, which is substantially flat, and radial fins 624. Briefly described, the flat surface 622 absorbs heat from the LEDs 610. The radial fins 624 radiate heat. Heat is carried away from the radial fins 624 by moving air. Air may move by convection or be propelled by a fan. The mounting surface 622 of the heatsink 620 includes a plurality of bores 626. Each bore 626 is positioned to be in registration with an aperture 604 in the frame 606.

The cutouts 608 define openings for receiving the LEDs 610. First and second cantilevered arms maintain each LED 610 in place in a manner similar to the embodiments of FIGS. 1-8.

The embodiment of FIGS. 9-11 demonstrates an unexpected way of maintaining substantially equal pressure on a plurality of the LEDs 610 in the lighting assembly 600. The cutouts 608 are arranged substantially symmetrically. When fasteners are placed to maintain the frame 606 in engagement with the surface 622, force is evenly distributed against the LEDs 610. Mechanical integrity and minimal stress are provided. Simplified wiring may also be provided.

In accordance with the present subject matter, an LED assembly and an LED assembly interacting with a light unit are provided in which assembly is simplified and reliability is maximized. Simplicity in assembly is facilitated by the provision of a frame that is relatively easily mounted to a surface and which conveniently receives LEDs. Connecting terminals of an LED on a circuit board to copper vias within the board minimizes steps in wiring and minimizes the presence of loose wires. The construction necessarily provides for heat dissipation. It is not necessary to optimize heat dissipation versus reliability in mechanical connection.

What is claimed is:

1. An LED apparatus comprising at least one LED, the LED comprising a light-emitting layer and a substrate, connected electrically, mechanically, and thermally within a lighting assembly, said lighting assembly comprising:
a substrate comprising a circuit board;
a light-emitting layer formed on the substrate, said LED having terminals for connection across a power source;
said frame and said substrate being disposed against a heat dissipating surface;
the frame having an opening formed to surround said substrate;
said frame being fixed to said heat dissipating surface; and
biasing components formed in said frame and positioned to bias said substrate against the heat dissipating surface, said biasing components positioned to distribute force applied to said substrate.

2. An apparatus according to claim 1 wherein the circuit board further comprises conductive vias for coupling power across the LED terminals, the LED terminals being positioned to be directly solderable to the conductive vias.

3. An apparatus according to claim 2 wherein each via is connectable across a power source.

4. An apparatus according to claim 3 wherein said biasing components comprise a plurality of cantilevered beams, each said cantilevered beam projecting from a side of the opening toward a center of the opening.

5. An apparatus according to claim 4 wherein said frame comprises an opening having a shape to surround the substrate, and wherein the biasing components are dimensioned with respect to a preselected LED to exert pressure on the substrate adjacent a boundary of the light-emitting layer.

6. An apparatus according to claim 5 wherein said plurality of cantilevered beams comprises first and second cantilevered beams mounted substantially opposite each other, each cantilevered beam having a selected spring constant in proportion to strength of the substrate.

7. An apparatus according to claim 6 wherein the LED comprises an emission layer and a substrate, the emission layer and substrate comprising a chip-on-board array.

8. An apparatus according to claim 7 wherein the emission layer comprises a circular emission area on the substrate.

9. An LED lighting apparatus comprising:
an LED apparatus housing having a heat dissipating surface;
an LED assembly mounted to the heat dissipating surface, the heat dissipating surface being mounted in registration with an aperture through which light from the LED assembly is projected;
the lighting fixture comprising a substrate and a frame surrounding said substrate;
said substrate and said frame being thermally coupled to and mechanically connected to said heat dissipating surface; and
said frame comprising biasing means engaging the substrate in a plurality of angular positions each adjacent the LED and providing for distribution of biasing force over the area of the substrate.

10. An LED lighting apparatus according to claim 9 wherein said heat dissipating surface comprises a surface of a chamber, the chamber being enclosed in the housing, said heat dissipating surface facing a planar area through which light is projected from the LED lighting apparatus.

11. An LED lighting apparatus according to claim 10 wherein said chamber comprises sidewalls surrounding the heat dissipating surface and defining a perimeter of the planar area.

12. An LED lighting apparatus according to claim 11 wherein a diffuser covers the planar area.

13. An LED lighting apparatus according to claim 12 wherein said chamber is mounted in a housing and wherein said diffuser comprises a closure member covering the chamber.

14. An LED assembly mountable to a heat-dissipating surface comprising:
a frame, said frame comprising a mounting section for bearing against the heat dissipating surface;
said frame having a central opening dimensioned to receive a preselected chip-on-board LED comprising a light-emitting layer formed on a substrate, the light-emitting layer having a perimeter confined within a perimeter of an upper surface of the substrate;
said frame having first and second arms projecting into said opening, each arm connected to its respective mounting section, and each arm having an effective spring constant;
said frame having a preselected thickness such that when the preselected LED is placed in the opening, a lower surface of the frame and a lower surface of the substrate are substantially coplanar in registration against the heat dissipating surface, said first and second arms bias said LED against the heat dissipating surface;
ends of said arms being shaped to be in vertical registration with said substrate and positioned to permit light to pass between respective ends of the first and second arms;
a unitary frame surrounding said substrate, said frame being dimensioned to cooperate with a preselected LED configuration and having an opening for receiving said substrate in a horizontal degree of freedom, said frame comprising biasing portions interfering with said substrate in a vertical degree of freedom when the lower surface of the substrate and a lower surface of the frame are in vertical registration, whereby said biasing portions bias the substrate in a direction extending from the upper surface of the substrate to the lower surface of the substrate; and
the opening and each said biasing portion comprising an arm defined by a cutout in the frame.

15. An LED assembly according to claim 14 wherein each said arm has a proximal end adjacent an outer extremity of the cutout and a distal end extending over the substrate, and comprising a leaf spring with a spring constant for optimizing magnitude of force against the substrate versus strength of the substrate.

16. An LED assembly according to claim 15 wherein said arms have ends shaped to match a perimeter of the light-emitting layer.

17. An LED assembly according to claim 15 wherein said frame forms a circle, said frame comprising a central cutout and a plurality of cutouts in each quadrant of the circle.

18. An LED assembly according to claim 14 further comprising the heat dissipating surface and wherein the heat dissipating surface comprises a heat sink having an upper surface proportion to engage a lower surface of the frame to conduct heat therefrom.

19. An LED assembly according to claim 14 wherein said substrate comprises a printed circuit board having a light-emitting section and a circuitry section and wherein said cutout includes areas to accommodate the light -emitting section and the circuitry section.

20. An LED assembly according to claim 19 wherein said printed circuit board comprises conductive vias, a first end of each conductive via is coupled to a power source.
